(19) United States
(12) Patent Application Publication
(10) Pub. No.: US 2016/0322273 A1
(43) Pub. Date: Nov. 3, 2016

(54) SIX-SIDED PROTECTION OF A WAFER-LEVEL CHIP SCALE PACKAGE (WLCSP)

(71) Applicant: NXP B.V., Eindhoven (NL)

(72) Inventors: Chi-Feng Wu, Kaohsiung (TW); Ting-Fong Bastiaan Simon Dai, Kaohsiung (TW); Chyi Keh Chern, Kaohsiung (TW)

(21) Appl. No.: 14/697,937

(22) Filed: Apr. 28, 2015

(51) Int. Cl. H01L 23/31; H01L 23/29; H01L 21/66; H01L 21/78; H01L 23/00; H01L 21/56

(52) U.S. Cl. CPC H01L 23/3114; H01L 24/83; H01L 21/565; H01L 24/14; H01L 22/14; H01L 21/561; H01L 21/78; H01L 24/94; H01L 24/29; H01L 23/3135; H01L 23/293; H01L 24/73; H01L 2224/13022; H01L 2224/118; H01L 2224/8385; H01L 2224/83191; H01L 2224/73253

(57) ABSTRACT

Consistent with an example embodiment, a WLCSP (wafer-level chip-scale package) device may be encapsulating in a six-sided protection envelope. The envelope is a molding compound or other resilient material. The encapsulated WLCSP device is protected from handling damage during assembly into the end user's system.

### FIELD

The embodiments of the present invention relate to semiconductor device packaging and, more particularly, to WLCSP packaging having modifications that protect the semiconductor die from handling damage so as to enhance the manufacturability and quality of products.

### BACKGROUND

The electronics industry continues to rely upon advances in semiconductor technology to realize higher-function devices in more compact areas. For many applications realizing higher-functioning devices requires integrating a large number of electronic devices into a single silicon wafer. As the number of electronic devices per given area of the silicon wafer increases, the manufacturing process becomes more difficult.

The packaging of an IC device is increasingly playing a role in its ultimate performance. For example, in mobile devices (i.e., mobile phones, tablet computers, laptop computers, remote controls, etc), WLCSP components are used in their assembly. WLCSP components save valuable space in the mobile device. After assembly, in some example processes, customers encapsulate these WLCSP devices by injection molding or casing. This manual post-processing of the bare WLCSP may result in device damage; therefore, generally, handling of the WLCSP devices should be minimized.

There is a need for a WLCSP assembly process which can address the challenges raised by the needs of mobile applications.

### SUMMARY

The present disclosure has been found useful in the packaging of semi-conductor devices which find their way into portable electronic devices. In particular, WLCSP (wafer-level chip-scale package) products which are furnished as unpackaged die to manufacturers of mobile devices, who in turn encapsulate these devices directly onto a printed circuit board, in an effort to conserve valuable space in the mobile device, may subject these unpackaged die to rough handling. The handling may result in cracking or other latent damage which may not show up until the mobile device reaches the end user. Refer to FIGS. 1A-1B. Unprotected devices during picking and placement onto a customer's system board have sustained mechanical damage and thus are not useable. Consequently, the customer may prefer to have the WLCSP product surrounded by non-brittle material, which prevents damage to the die itself, before receiving the product for assembly in to his mobile device.

The user places device die onto a carrier strip. The device die have an underside surface and an opposite topside surface. On the topside surface the active IC circuit is present. The underside surface is attached to the carrier strip with an adhesive resilient material. Solder bumps have been applied to bond pads on the active device. Through processing, the unpackaged die are protected on their underside surfaces and their respective vertical surfaces with a resilient protective layer of material. The protective layer of material absorbs the shocks of manual handling during assembly of the mobile device.

According to a first aspect of the present disclosure, there is provided a method for assembling a plurality of wafer level chip scale processed (WLCSP) devices, the plurality of WLCSP devices having topside surfaces, underside surfaces, and vertical faces, the plurality of devices having electrical contacts on the topside surfaces, the electrical contacts having solder bumps defined thereon. The method comprises applying a resilient adhesive material so as to contact the underside surfaces of the plurality of WLCSP devices and bond the plurality of WCLSP devices to the carrier strip; mounting the plurality of WLCSP devices onto a carrier strip, the WLCSP devices arranged in an array of devices spaced apart from one another by a prescribed distance; over-molding the array of devices on the carrier strip with a molding compound, the molding compound enveloping the plurality of devices and covering the solder bumps, the molding compound substantially encapsulating the solder bumps; and de-capsulating the solder bumps in the array of devices.

In an example embodiment, applying the resilient material further includes at least one of the following: applying resilient adhesive material onto the carrier strip, applying resilient adhesive material directly onto the underside surfaces of the plurality of WLCSP devices, or a combination thereof.

In an example embodiment, the resilient material is at least one of the following: die-attach film (DAF), wafer backside plastic.

In an example embodiment, the resilient material is the molding compound used in the over-molding of the array of devices.

In an example embodiment the method further comprises, performing an in-strip electrical testing of each of the plurality of WLCSP devices.

In an example embodiment the method further comprises, singulating the array of devices into individual devices, wherein the individual devices each have a protective layer on the vertical faces and surrounding the solder bumps on the topside surface, and a protective layer on the underside surface.

In an example embodiment the method further comprises, the protective layer is selected from at least one of the following: poly-oxydiphenylene-pyromellitimide, polytetrafluoroethylene, molding compound, film on wire (FOW).

In an example embodiment the method further comprises the thickness of the protective layer on the back-side surface is at least 25 μm.

In an example embodiment the method further comprises the de-capsulating the solder bumps exposes at least half of a thickness of the solder bumps.

In an example embodiment, de-capsulating the solder bumps is performed with a least one of the following: laser ablation, plasma etching.

In an example embodiment, the protective layer is selected from at least one of the following: poly-oxydiphenylene-pyromellitimide, polytetrafluoroethylene, molding compound, film on wire (FOW).

According to a second aspect of the present disclosure, there is provided a method for assembling a plurality of wafer level chip scale processed (WLCSP) devices. The plurality of WLCSP devices have topside surfaces, underside surfaces, and vertical faces; the plurality of devices have electrical contacts on the topside surfaces, the electrical contacts having solder bumps defined thereon. The method comprises applying a molding compound so as to contact the underside surfaces of the plurality of WLCSP devices and bond the plurality of WCLSP devices to the carrier strip. Applying the molding compound further includes at least one of the following: applying molding compound onto the carrier strip, applying molding compound directly onto the underside surfaces of the plurality of WLCSP devices, or a combination thereof. The thickness of the molding compound on the underside surfaces of the plurality of WLCSP devices is at least 25 μm. Mounting the plurality of WLCSP devices onto a carrier strip, the WLCSP devices are arranged in an array of devices spaced apart from one another by a prescribed distance. With an over-molding the array of devices on the carrier strip with a molding compound, the molding compound envelopes the plurality of devices and covers the solder bumps, the molding compound substantially encapsulates the solder bumps. The solder bumps in the array of devices are decapsulated, wherein the de-capsulating the solder bumps exposes at least half of a thickness of the solder bumps. An in-strip electrical testing is performed on each of the plurality of WLCSP devices. After electrical testing the array of devices is singulated into individual devices. The individual devices each have a protective layer of molding compound on the vertical faces and surrounding the solder bumps on the topside surface, and a protective layer of molding compound on the underside surface.

According to a third aspect of the present disclosure there is a WLCSP device comprising a device die having a topside surface and an underside surface, and four vertical side surfaces. A protective layer is applied to the top-side surface, the underside surface and the four vertical faces of the WLCSP device; wherein the top-side surface of the WLCSP, has solder bumps defined thereon. A protective layer surrounds each one of the solder bumps, and the protective layer has a thickness is about half the height of the solder bumps.

The above summaries are not intended to represent each disclosed embodiment, or every aspect, of the present disclosure. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIGS. 1A-1B (Prior Art) are example photo-micrographs of WLCSP devices damaged during pick and place handling as the devices are surface-mounted onto a system printed circuit board (PCB);

FIG. 2 is a flow diagram of an assembly process according to an embodiment of the present disclosure;

FIGS. 3A-3F in a series of side views, illustrate an assembly process of a six-sided protected WLCSP according to a disclosed embodiment; and

FIGS. 4A-4C illustrate some steps of the assembly process of a six-sided protected WLCSP according to the disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

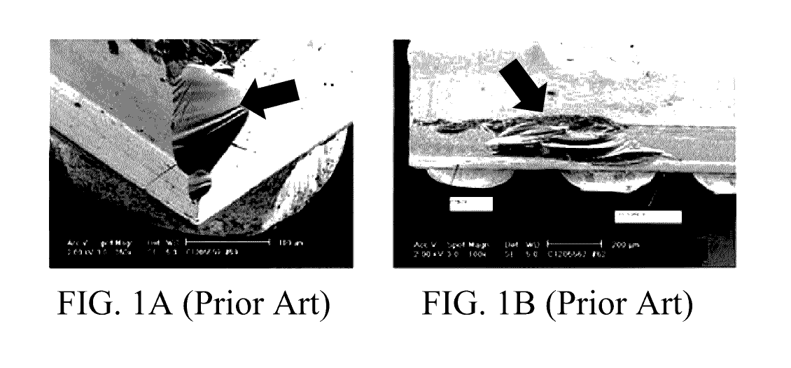

The disclosed embodiments have been found useful in preventing damage to the Wafer Level Chip-Scale Product (WLCSP) devices during their assembly. The process provides mechanical protection to the silicon device by mounting the device into a resilient layer of protective material which envelopes the device die; the protective material forms a barrier on the device's exposed surfaces that keeps assembly tooling from directly contacting the silicon device, thus avoiding chipping and other damage. Refer to FIGS. 1A-1B.

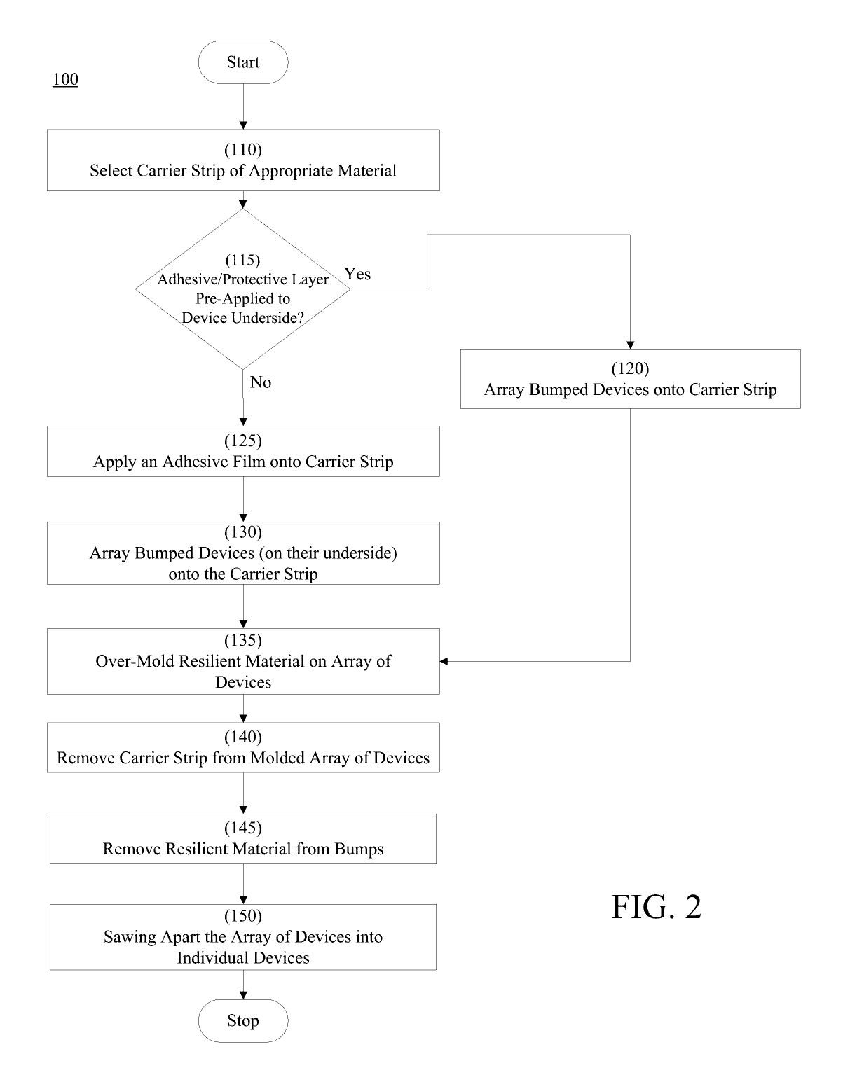

Refer to FIG. 2. The series of steps is outlined in an assembly flow 100. In step 110 the carrier strip is selected. Depending upon the manufacturing process or tooling, the carrier strip may be made of metal or a plastic material. In one example process, at step 125, an adhesive film may be applied to the carrier strip. In another example process, steps 115, 120, the device die (each die having bumps already defined on their top-side surface) may have had an adhesive applied to their underside surfaces before their attachment to the carrier strip.

In another example embodiment, a protective resilient coating may have already been applied to the underside surface of the wafer during its production. More information may be found in U.S. patent application Ser. No. 14/322,304 titled, “Flexible Wafer-Level Chip Scale Packages with Improved Board-Level Reliability” by Caroline Beelen-Hendrikx et al, filed on Jul. 2, 2014 and assigned to NXP, B. V. Eindhoven, Netherlands and is incorporated by reference in its entirety.

In step 130, the bumped devices are attached in an arrayed layout (of rows and columns) of devices. In step 135, the arrayed devices are over-molded in a molding compound. After the over-molding, in step 140, the carrier strip is removed. In step 145, the array of molded devices undergoes a process to remove the resilient material from the bumps. The removal of the resilient material may be done, for example, with a plasma etching process, for example. The etching proceeds until a predetermined portion of the solder bumps is exposed. Having exposed the solder bumps, in step 150, the array of devices is sawed apart into individual packaged WLCSP devices. The individual device is protected on its six-sides; the top-side surface, the underside surface, and the four vertical faces. Thus, the likelihood of damage that may be encountered, as shown in FIGS. 1A-1B, is reduced.

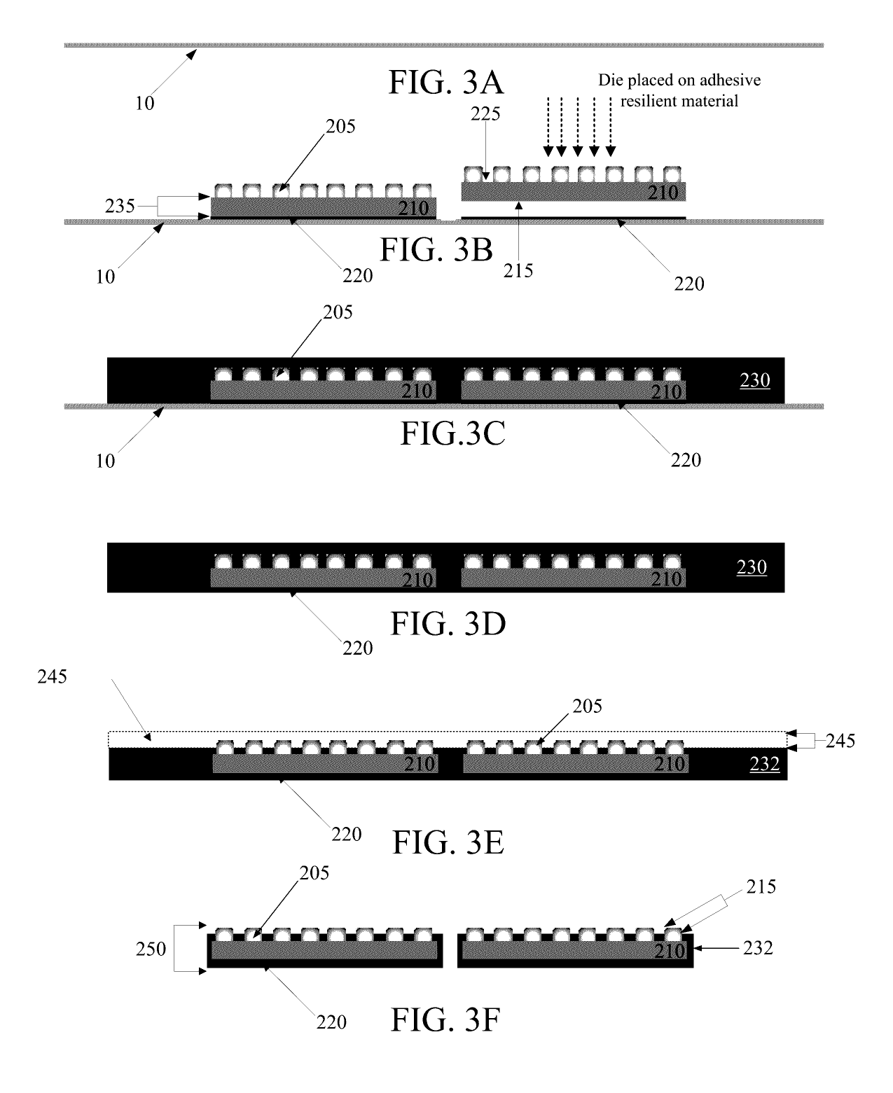

Refer to FIGS. 3A-3F. In a series of side views, a plurality of device die are assembled according to the present disclosure. Refer to FIGS. 3A-3B. A carrier strip 10 provides a platform for the placement of individual device die 210. A plurality of device die 210 having a topside surface 225 with active circuit elements and bond pads to which solder bumps 205 are applied, attached with adhesive resilient compound 220 on an underside surface 215 of the device die 210. The carrier strip 10 may be metal, plastic, or glass. For metal carriers, this may include copper (Cu), stainless steel, or SPTE (steel plated-tin, electrolytic), etc. The number of solder balls may range from two, for a diode device to packages having an 11×11 solder ball arrangement. However, the present disclosure is not so limited.

In an example process, the adhesive resilient compound 225 may be applied to a wafer substrate prior to singulation into individual device die 210. The individual device die 210 having a protective resilient compound 220 are taken from the wafer substrate and placed upon the carrier strip 10. More flexible resilient layers e.g. KAPTON foils can be laminated to the silicon wafers using a pre-applied adhesive on the foil or alternatively an adhesive on the Si-wafer.

Refer to FIG. 3C. Having mounted the plurality of device die 210 onto the carrier strip 10, the plurality of device die 210 are encapsulated in a plastic molding compound 230. The plastic molding compound 230 envelopes vertical side faces of the device die 210 and the solder bumps 205. The carrier strip 10, is removed after the encapsulation, as shown in FIG. 3D.

TABLE 1
Dimensions of Features of Example Embodiment

| | Reference | |
|---|---|---|
| | Number | Dimensions |
| Description of Feature | FIGS. 3A-3F | (μm) |
| Completed Assembled Package | 250 | 325 |
| (includes Ball) | | |
| Solder Ball | 205 | 200 |
| Exposed Portion Solder Ball | 215 | 100 |
| Die-Attach Film | 220 | 25 |
| Molding Compound Thickness | 230 | 360 |
| Applied | | |
| Die Thickness | 235 | 100 |
| Molding Compound Removed | 245 | 135 |
| (by “Laser Ablation”) | | |
| Molding Compound Thickness | 232 | 225 |
| (after “Laser Ablation”) | | |

The plastic material may be made of, but not necessarily limited to, KAPTON®, PTFE (polytetrafluoroethylene), molding compound, etc. KAPTON is the brand name of the polyimide film (i.e., poly-oxydiphenylene-pyromellitimide) manufactured by the E.I. du Pont de Nemours and Company. The plastic molding compound 230 and adhesive resilient compound 220 must withstand a temperature range of about 200° C. to 300° C. usually encountered in the reflow process for WLCSP device assembly. Other flexible protective materials may include, but not necessarily limited to, polytetra-fluoroethylene. Some molding compounds, may include, but not necessarily limited to, those manufactured by Sumitomo (e.g.: x84194) and Hitachi (e.g.: cel 400 ZHF 40 53 C), etc.

Refer to FIGS. 3E-3F. Having removed the carrier strip 10, the molding compound 230 is removed (i.e, the solder bumps are de-capsulated) from the solder bumps 205 so as to expose their conductive surfaces 215; the bumps 205 are surrounded by remaining molding compound 232. After removing a prescribed thickness 245 of the molding compound 230, the plurality of devices 210 are separated by sawing into individual devices 250. In an example process, laser ablation may be used to remove a prescribed portion 245 of the molding compound 230. In another example process, a plasma etch process may be used to remove the prescribed portion 245 of molding compound 230. The individual devices 250 with exposed bumps 215 are enveloped in a molding compound 232 on the bump side (topside) of the device die 210 and the vertical faces surrounding the device die 210; the resilient coating 220 protects the underside surface of the device die 210.

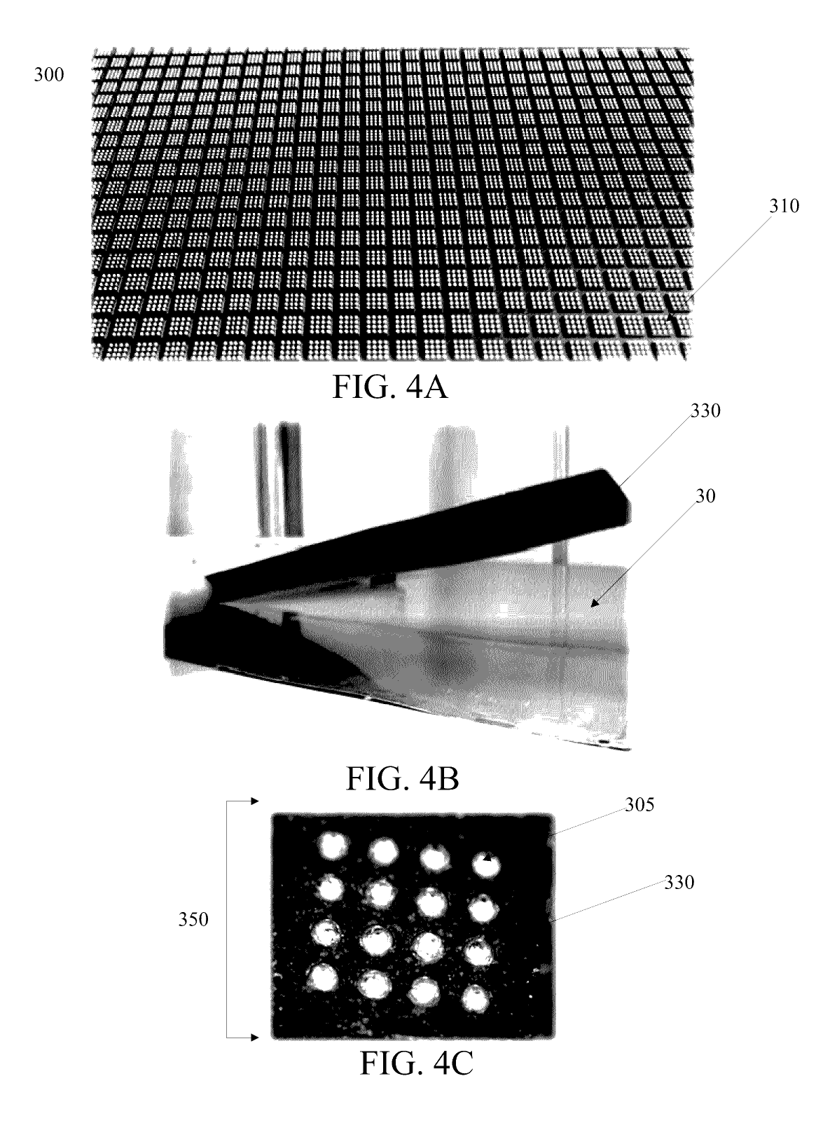

Refer to FIGS. 4A-4C. In an example embodiment an array 300 of WLCSP devices 310 are on a carrier 30. The user has performed the six-sided protective molding process. The array 300 of WLCSP devices 310 in the resilient molding material 330 is removed from the carrier 30. An individual device 350 has its solder bumps 305 enveloped by the resilient molding material 330. Prior to separating the array of WLCSP active device die, it is possible to perform an “in-strip” electrical test on each of the devices.

The embodiments discussed, protect both the underside surface and vertical faces of the WLCSP device against mechanical impacts from subsequent handling during assembly (i.e., tweezers, pipettes, vacuum wands, etc.).

Numerous other embodiments of the invention will be apparent to persons skilled in the art without departing from the spirit and scope of the invention as defined in the appended claims.

1. A method for assembling a plurality of wafer level chip scale processed (WLCSP) devices, the plurality of WLCSP devices having topside surfaces, underside surfaces, and vertical faces, the plurality WLCSP devices having electrical contacts on the topside surfaces, the electrical contacts having solder bumps defined thereon, the method comprising:
applying a resilient adhesive material so as to contact the underside surfaces of the plurality of WLCSP devices and bond the plurality of WLCSP devices to a carrier strip, the carrier strip providing a device-placement platform having a contiguous planar surface;
mounting the plurality of WLCSP devices onto the contiguous planar surface, the WLCSP devices arranged in an array of devices respectively separated by spacings each defined by a prescribed distance, wherein the spacings between the WLCSP devices are contained by corners at which respective vertical faces of the WLCSP devices meet the contiguous planar surface;
over-molding the array of devices on the contiguous planar surface with a molding compound, the molding compound enveloping the plurality of WLCSP devices and covering the solder bumps, the molding compound substantially encapsulating the solder bumps; and
de-capsulating the solder bumps in the array of devices.

2. The method as recited in claim 1, wherein applying the resilient material further includes at least one of the following:
applying resilient adhesive material onto the carrier strip,
applying resilient adhesive material directly onto the underside surfaces of the plurality of WLCSP devices prior to singulation into individual device die, or
a combination thereof, and
wherein the molding compound occupies or fills the spacings.

3. The method as recited in claim 2, wherein the resilient adhesive material is at least one of the following: die-attach film (DAF), wafer backside plastic.

4. The method as recited in claim 2, wherein the resilient adhesive material is the molding compound used in the over-molding of the array of devices.

5. The method as recited in claim 1, further comprising,
performing an in-strip electrical testing of each of the plurality of WLCSP devices.

6. The method as recited in claim 1, further comprising,
singulating the array of devices into individual devices, wherein the individual devices each has a protective layer on the vertical faces and surrounding the solder bumps on the topside surface, and a protective layer on the underside surface.

7. The method as recited in claim 6, wherein the protective layer is selected from at least one of the following: poly-oxydiphenylene-pyromellitimide, polytetrafluoroethylene, molding compound, film on wire (FOW).

8. The method as recited in claim 6, wherein, the thickness of the protective layer on the back-side surface is at least 25 μm.

9. The method as recited in claim 1, wherein the de-capsulating the solder bumps exposes at least half of a thickness of the solder bumps.

10. The method as recited in claim 1, wherein de-capsulating the solder bumps is performed with a least one of the following: laser ablation, plasma etching.

11. A method for assembling a plurality of wafer level chip scale processed (WLCSP) devices, the plurality of WLCSP devices having topside surfaces, underside surfaces, and vertical faces, the plurality of WLCSP devices having electrical contacts on the topside surfaces, the electrical contacts having solder bumps defined thereon, the method comprising:
applying a molding compound so as to contact the underside surfaces of the plurality of WLCSP devices and bond the plurality of WLCSP devices to a carrier strip providing a device-placement platform having a contiguous planar surface;
wherein applying the molding compound further includes at least one of the following:
applying molding compound onto the carrier strip,
applying molding compound directly onto the underside surfaces of the plurality of WLCSP devices, or
a combination thereof;
wherein the thickness of the molding compound on the underside surfaces of the plurality of WLCSP devices is at least 25 μm;
mounting the plurality of WLCSP devices onto the contiguous planar surface, the WLCSP devices arranged in an array of devices respectively separated by spacings each defined by a prescribed distance, wherein the spacings between the WLCSP devices are contained by corners at which respective vertical faces of the WLCSP devices meet the contiguous planar surface;
over-molding the array of devices on the the contiguous planar surface with a molding compound, the molding compound enveloping the plurality of WLCSP devices and covering the solder bumps, the molding compound substantially encapsulating the solder bumps;
de-capsulating the solder bumps in the array of devices;
wherein the de-capsulating the solder bumps exposes at least half of a thickness of the solder bumps;
performing an in-strip electrical testing of each of the plurality of WLCSP devices; and
singulating the array of devices into individual devices, wherein the individual devices each have a protective layer of molding compound on the vertical faces and surrounding the solder bumps on the topside surface, and a protective layer of molding compound on the underside surface.

12. (canceled)

13. The method of claim 11, further including applying resilient adhesive material directly onto the underside surfaces of the plurality of WLCSP devices prior to singulation into individual device die.

14. The method of claim 11, wherein over-molding the array of devices on the contiguous planar surface with the molding compound further includes encapsulating the plurality of WLCSP devices in the molding compound and the spacings.

15. The method of claim 11, further including removing the carrier strip after over-molding.

16. A method for assembling a plurality of wafer level chip scale processed (WLCSP) devices, the plurality of WLCSP devices having topside surfaces, underside surfaces, and vertical faces, the plurality of WLCSP devices having electrical contacts on the topside surfaces, the electrical contacts having solder bumps defined thereon, the method comprising:
applying a molding compound directly onto the underside surfaces of the plurality of WLCSP devices prior to singulation into individual device die so as to contact the underside surfaces of the plurality of WLCSP devices and bond the plurality of WLCSP devices to a carrier strip providing a device-placement platform having a contiguous planar surface;
mounting the plurality of WLCSP devices onto the contiguous planar surface, the WLCSP devices arranged in an array of devices respectively separated by spacings,. wherein the spacings between the WLCSP devices are contained by corners at which respective vertical faces of the WLCSP devices meet the contiguous planar surface;
over-molding the array of devices on the contiguous planar surface with a molding compound, the molding compound enveloping the plurality of WLCSP devices and covering the solder bumps, the molding compound substantially encapsulating the solder bumps and the spacings;
removing the carrier strip from the array of devices in the molding compound;
de-capsulating the solder bumps in the array of devices by exposing at least half of a thickness of the solder bumps from the molding compound; and
singulating the array of devices into individual devices, wherein the individual devices each have a protective layer of molding compound on the vertical faces and surrounding the solder bumps on the topside surface, and a protective layer of molding compound on the underside surface.

17. The method of claim 16, wherein de-capsulating the solder bumps is performed using laser ablation to expose at least half of the thickness of the solder bumps from the molding compound.

18. The method of claim 16, wherein de-capsulating the solder bumps is performed using plasma etching to expose at least half of the thickness of the solder bumps.

19. The method of claim 16, further including applying an adhesive for attaching the plurality of WLCSP devices along the contiguous planar surface of the device-placement platform.

20. The method as recited in claim 1, further including applying an adhesive for attaching the plurality of WLCSP devices along the contiguous planar surface of the device-placement platform.
